(19) United States
(12) Patent Application Publication
(10) Pub. No.: US 2026/0029437 A1
(43) Pub. Date: Jan. 29, 2026

(54) Power Module

(71) Applicants: HYUNDAI MOTOR COMPANY, Seoul (KR); KIA CORPORATION, Seoul (KR)

(72) Inventors: Dong Hwan Lee, Hwaseong-si (KR); Suk Hyun Lim, Hwaseong-si (KR); Han Jin Do, Hwaseong-si (KR)

(73) Assignees: HYUNDAI MOTOR COMPANY, Seoul (KR); KIA CORPORATION, Seoul (KR)

(21) Appl. No.: 19/083,738

(22) Filed: Mar. 19, 2025

Related U.S. Application Data
(63) Continuation of application No. 18/967,528, filed on Dec. 3, 2024.

(30) Foreign Application Priority Data
Jul. 24, 2024 (KR) 10-2024-0098207

(51) Int. Cl. G01R 15/20; G01R 19/00; H05K 1/02; H05K 1/18

(52) U.S. Cl. CPC G01R 15/202; G01R 19/0092; H05K 1/0213; H05K 1/181; H05K 2201/10151

(57) ABSTRACT

A power module is configured to provide sensing current through a Hall element. By sensing current through a Hall element, reducing the volume and cost for current sensing can be provided. In addition, by reducing the influence of eddy currents on the Hall element, the sensing accuracy of the Hall element may be improved.

### CROSS REFERENCE TO RELATED APPLICATIONS

The present application is a continuation of U.S. patent application Ser. No. 18/967,528, filed Dec. 3, 2024, which claims the benefit of priority under 35 U.S.C. § 119(a) from Korean Patent Application No. 10-2024-0098207, filed Jul. 24, 2024, the entire contents of which are incorporated herein for all purposes by this reference.

### TECHNICAL FIELD

The present disclosure relates to a power module that enables sensing current through a Hall element provided therein and improves the sensing accuracy of the Hall element by reducing the influence of eddy currents on the Hall element.

### BACKGROUND

As interest in the environment is growing, the number of eco-friendly vehicles equipped with an electric motor as a power source is increasing. Eco-friendly vehicles are also called electrified vehicles, and representative examples include electric vehicles (EVs) and hybrid electric vehicles (HEVs).

Electrified vehicles are provided with an inverter to convert direct current (DC) power to alternating current (AC) power when a motor is driven, and the inverter may be composed of one or more power modules equipped with a semiconductor chip that performs a switching function.

Meanwhile, during operation of a power module, a semiconductor chip produces heat due to high voltage and large current. In this way, when the temperature of the power module rises due to the heat generated from the semiconductor chip, the operation of the power module is affected. Therefore, heat generation facilitates stable operation of the power module.

Accordingly, various cooling methods are being applied to reduce heat generation in a power module. For example, by connecting a cooling channel to a substrate and flowing refrigerant through the cooling channel, cooling efficiency is improved through heat exchange between the refrigerant and the substrate.

In order to control the power conversion system of a vehicle including a power module, the electric current of the power module is sensed. For this purpose, a current sensor is provided outside the power module, or a resistor such as a shunt resistor is provided inside the power module.

However, if a current sensor is provided outside the power module, the overall size increases, and when sensing current inside the power module, sensing accuracy is reduced due to surrounding interference factors.

The description provided above as a related art of the present disclosure is for helping understand the background of the present disclosure and should not be construed as being included in the related art known by those skilled in the art.

### SUMMARY

An objective of the present disclosure is to provide a power module that enables sensing current through a Hall element provided therein, thereby reducing the volume and cost for current sensing.

In addition, an objective of the present disclosure is to provide a power module that improves the sensing accuracy of a Hall element by reducing the influence of eddy currents on the Hall element.

In order to achieve the objectives of the present disclosure, there is provided a power module including a substrate provided with a semiconductor chip and a metal conductive part through which an electric current flows, a sensor part installed on the metal conductive part of the substrate and configured to sense the current flowing in the semiconductor chip or the metal conductive part, and an eddy current reduction pattern part configured to reduce an eddy current around the sensor part by dividing the metal conductive part around the sensor part into a plurality of segments.

The eddy current reduction pattern part may be configured such that a segment among the plurality of segments where the sensor part is provided is electrically separated from other segments among the plurality of segments.

The eddy current reduction pattern part may be configured such that segments other than a segment where the sensor part is provided among the plurality of segments are divided into multiple segments.

The eddy current reduction pattern part may include a certain range of pattern shapes around a segment among the plurality of segments where the sensor part is provided.

The sensor part may be electrically connected to an outside through a signal pin.

In the metal conductive part of the substrate, a segment among the plurality of segments provided with a sensor part and a segment among the plurality of segments for connecting the signal pin may be separated by the eddy current reduction pattern part, and the sensor part may be electrically connected to the segment to which the signal pin is connected.

The sensor part may be electrically connected to the signal pin through at least one of a wire bonding connection or bonding to the signal pin.

The substrate may include a first substrate and a second substrate, and the sensor part may be provided on either the first substrate or the second substrate and senses the current flowing in the metal conductive part of the opposing substrate.

The first substrate may include a first insulation part, and a first metal conductive part and a second metal conductive part respectively disposed on opposite sides of the first insulation part centered on the first insulation part, whereas the second substrate may include: a second insulation part, and a third metal conductive part and a fourth metal conductive part respectively disposed on opposite sides of the second insulation part centered on the second insulation part, and the sensor part may be provided in either the second metal conductive part or the third metal conductive part.

A first eddy current reduction pattern part may be provided in the first metal conductive part in a form that covers the sensor part and a periphery of a portion matching the sensor part.

The second metal conductive part may be divided into a plurality of segments by a second eddy current reduction pattern part, and the sensor part may be arranged to match a portion where a current path is formed among the plurality of segments of the second metal conductive part.

The second eddy current reduction pattern part may include a certain range of pattern shapes around the sensor part in a segment among the plurality of segments matching the sensor part.

The third metal conductive part may include a certain range of pattern shapes around the sensor part.

A fourth eddy current reduction pattern part may be provided in the fourth metal conductive part in a form that covers the sensor part and a periphery of a portion matching the sensor part.

In the first metal conductive part, a first eddy current reduction pattern part having a repeated pattern shape may be provided that covers the sensor part and a periphery of a portion matching the sensor part, and in the fourth metal conductive part, a fourth eddy current reduction pattern part having a repeated pattern shape may be provided to cover the sensor part and the periphery of the portion matching the sensor part.

In the second metal conductive part, a second eddy current reduction pattern part may be provided around the sensor part, and the second eddy current reduction pattern part may be formed in a repeated pattern shape, and in the third metal conductive part, a third eddy current reduction pattern part may be provided around the sensor part, and the third eddy current reduction pattern part may have a repeated pattern shape but may be formed in a different pattern shape from the second eddy current reduction pattern part.

The sensor part may be a Hall element that generates a voltage by using a magnetic field produced by the current flowing in the metal conductive part of the substrate.

The sensor part may be bonded to the substrate in a form of a bare die.

According to the power module with the structure described above, it is possible to sense current through a Hall element provided therein, thereby reducing the volume and cost for current sensing. Furthermore, by reducing the influence of eddy currents on the Hall element, the sensing accuracy of the Hall element can be improved.

### BRIEF DESCRIPTION OF THE DRAWINGS

FIG. 1 is a view showing a power module according to an embodiment of the present disclosure.

FIG. 2 is a view showing an example of an eddy current reduction pattern part in the power module shown in FIG. 1.

FIG. 3 is a view showing another example of the eddy current reduction pattern part in the power module shown in FIG. 1.

FIG. 4 is a view showing still another example of the eddy current reduction pattern part in the power module shown in FIG. 1.

FIG. 5 is a view showing a first substrate and a second substrate of the power module according to an embodiment of the present disclosure.

FIG. 6 is a view showing the second substrate of the power module according to an embodiment of the present disclosure.

FIG. 7 is a view showing the top surface of the first substrate.

FIG. 8 is a view showing the bottom surface of the first substrate.

FIG. 9 is a view showing the top surface of the second substrate.

FIG. 10 is a view showing the bottom surface of the second substrate.

### DETAILED DESCRIPTION

Hereafter, embodiments of the present disclosure will be described in detail with reference to the accompanying drawings and the same or similar components are given the same reference numerals regardless of the numbers of figures and are not repeatedly described.

Terms “module” and “unit” that are used for components in the following description are used only for the convenience of description without having discriminate meanings or functions.

In the following description, if it is decided that the detailed description of known technologies related to the present disclosure makes the subject matter of the embodiments described herein unclear, the detailed description is omitted. Further, the accompanying drawings are provided for easy understanding of embodiments disclosed in the specification, and the technical spirit disclosed in the specification is not limited by the accompanying drawings, and all changes, equivalents, and replacements should be understood as being included in the spirit and scope of the present disclosure.

Terms including ordinal numbers such as “first”, “second”, etc. may be used to describe various components, but the components are not to be construed as being limited to the terms. The terms are used to distinguish one component from another component.

It is to be understood that when one element is referred to as being “connected to” or “coupled to” another element, it may be connected directly to or coupled directly to another element or be connected to or coupled to another element, having the other element intervening therebetween. On the other hand, it should to be understood that when one element is referred to as being “connected directly to” or “coupled directly to” another element, it may be connected to or coupled to another element without the other element intervening therebetween.

Singular forms are intended to include plural forms unless the context clearly indicates otherwise.

It will be further understood that the terms “comprise” or “have” used in this specification, specify the presence of stated features, steps, operations, components, parts, or a combination thereof, but do not preclude the presence or addition of one or more other features, numerals, steps, operations, components, parts, or a combination thereof.

Hereinafter, a power module according to a preferred embodiment of the present disclosure will be described with reference to the attached drawings.

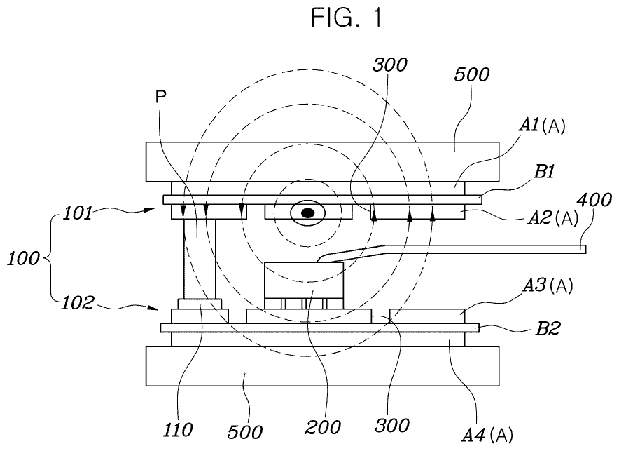

As shown in FIG. 1, a power module according to an embodiment of the present disclosure includes a substrate 100 provided with a semiconductor chip 110 and a metal conductive part A through which current flows, a sensor part 200 that is installed on the metal conductive part A of the substrate 100 and senses the current flowing in the semiconductor chip 110 or the metal conductive part A, and an eddy current reduction pattern part 300 that reduces eddy currents around the sensor part 200 by dividing the metal conductive part A around the sensor part 200 into a plurality of segments S.

FIG. 1 shows components related to the description of embodiments of the present disclosure, and an actual power module may be implemented by including more or fewer components. Hereinafter, each configuration of a power module according to embodiments of the present disclosure will be described.

The substrate 100 is provided with the planar metal conductive part A, and the metal conductive part A may be further provided with an insulation part. The metal conductive part A is configured to conduct electricity inside the power module, and the insulation part may be configured to electrically disconnect the inside and outside of the power module.

The substrate 100 has the eddy current reduction pattern part 300 provided on the metal conductive part A, and a current path may be determined depending on the shape of the eddy current reduction pattern part 300.

In addition, the semiconductor chip 110 may be provided on the substrate 100, and the semiconductor chip 110 may be connected to the metal conductive part A via bonding. The semiconductor chip 110 may be turned on/off according to a switching signal, may be implemented as a switching element such as an insulated gate bipolar transistor (IGBT) or a metal-oxide-semiconductor field-effect transistor (MOSFET), and may be made of silicon (Si) or silicon carbide (SiC).

In the present disclosure, the sensor part 200 is installed on the metal conductive part A of the substrate 100 and senses the current flowing in the semiconductor chip 110 or the metal conductive part A. The sensor part 200 may be electrically connected to the outside and may be electrically connected to the metal conductive part A of the substrate 100.

The sensor part 200 may be bonded to the substrate 100 in the form of a bare die and electrically connected to the metal conductive part A. The bare die form may be implemented in a state before the sensor part 200 and accessories are packaged.

In addition, the sensor part 200 may be bonded to the metal conductive part A by soldering or sintering. Instead of bonding the (e.g. entire) area, a method of bonding in the form of a solder ball to the area requiring electrical connection may be applied. In addition, the joining of the sensor part 200 may be implemented in various ways within the range of electrical connection possible.

Meanwhile, the sensor part 200 may be composed of a Hall element that generates a voltage according to a magnetic field generated by a current flowing in the metal conductive part A of the substrate 100.

To be specific, the sensor part 200 is configured to sense the current inside the power module by utilizing the Hall effect, which is the production of voltage in response to changes in a magnetic field. The sensor part 200 may specify a portion of the metal conductive part A where a current path is formed or the semiconductor chip 110, and the sensor part 200 may sense the current through a magnetic field generated by the current at that location.

In this way, by providing the sensor part 200 inside the power module, compared to the case where a sensor part is provided outside a power module, the influence of other external components on a magnetic field may be alleviated, thereby improving sensing performance.

In addition, compared to the case of sensing current through a built-in shunt resistor, the influence of temperature changes due to heat generation of a resistor on sensing may be mitigated, and current sensing may be performed in a relatively small space. As a result, it is possible to reduce the volume of a power module, and furthermore, it is possible to provide room in the internal space of an inverter where the power module is mounted.

In addition, in the present disclosure, the metal conductive part A around the sensor part 200 is divided into the plurality of segments S by the eddy current reduction pattern part 300.

One of the factors that reduces sensing accuracy in a structure where the sensor part 200 is provided inside the power module is an eddy current generated in the metal conductive part A. The eddy current is proportional to the flow of current flowing in the metal conductive part A and the frequency of current flow, and thus the wider the range of the metal conductive part A, the greater the effect of the eddy current on the sensor part 200.

As the metal conductive part A of the substrate 100 is divided into the segments S by the eddy current reduction pattern part 300, the flow of eddy current is impeded and resistance is increased, and the effect on the sensor part 20 caused by the eddy current may be reduced.

The eddy current reduction pattern part 300 may be configured so that the segment S where the sensor part 200 is provided is electrically separated from other segments S.

When the segment S where the sensor part 200 is provided is electrically connected to another segment S, the sensor part 200 may sense the current flow in a specific portion of the semiconductor chip 110 or the metal conductive part A, which may increase errors. That is, to mitigate the influence of large currents inside the power module during the current sensing process by means of the sensor part 200, the segment S where the sensor part 200 is provided is electrically separated from other segments S.

In addition, the eddy current reduction pattern part 300 may be configured so that other segments S except the segment S where the sensor part 200 is provided are separated into a plurality of segments S.

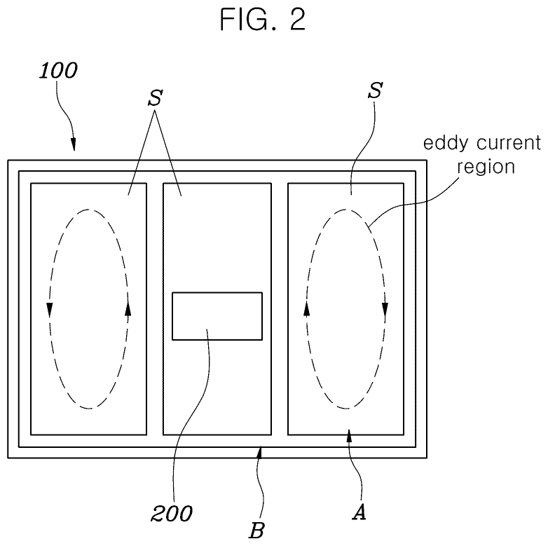

As an example, as shown in FIG. 2, the eddy current reduction pattern part 300 may be configured to divide the metal conductive part A of the substrate 100 into separate segments S on opposite sides, respectively, centered on the sensor part 200, so that eddy currents are reduced in each of the segments S on opposite sides.

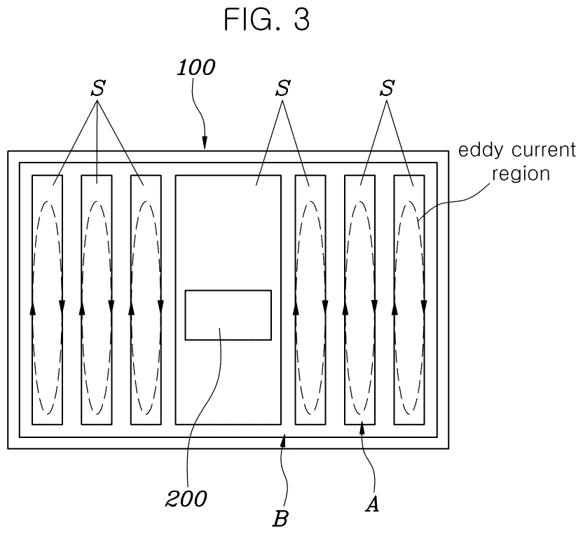

As another example, as shown in FIG. 3, the eddy current reduction pattern part 300 may be configured to divide the metal conductive part A of the substrate 100 into a plurality of segments S on opposite sides centered on the sensor part 200, and the division of the segments S on opposite sides may be performed along the longitudinal direction of the power module. In this case, the longitudinal direction of the power module may be a left-right direction in FIG. 3.

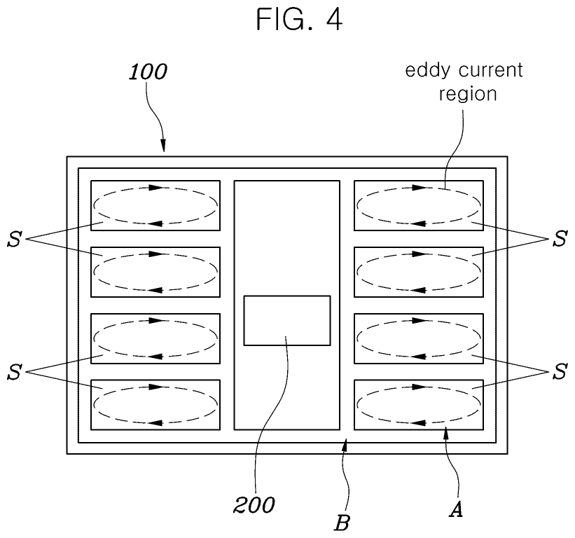

As still another example, as shown in FIG. 4, the eddy current reduction pattern part 300 may be configured to divide the metal conductive part A of the substrate 100 into a plurality of segments S on opposite sides centered on the sensor part 200, and the division of the segments S on opposite sides may be performed in a direction perpendicular to the longitudinal direction of the power module. That is, the division of the segments S on opposite sides may be performed in the vertical direction in FIG. 4.

Examples of dividing the metal conductive part A into the plurality of segments S by the eddy current reduction pattern part 300 described above are not limited thereto, and the plurality of segments S may be separated in various forms. Factors that determine the separation of the segments S may be the installation location and number of semiconductor chips 110, and/or connection locations of spacers, and each segment S may be separated to have various shapes depending on the current path.

Due to this, in the present disclosure, the influence of eddy currents on the Hall element may be reduced and the sensing accuracy of the Hall element may be improved.

Meanwhile, the eddy current reduction pattern part 300 may include a (e.g. certain) range of pattern shapes around the segment S where the sensor part 200 is provided.

That is, the eddy current reduction pattern part 300 is provided to extend to a (e.g., certain) range around the sensor part 200 in the metal conductive part A of the substrate 100, thereby reducing the influence of eddy current generation on the sensor part 200. At this time, the eddy current reduction pattern part 300 may be applied in a pattern shape covering a (e.g., certain) range around the sensor part 200, and in this case, the pattern may be applied in various forms such as a grid, a straight line, or an oblique line.

In addition, the eddy current reduction pattern part 300 may be applied to the periphery of the sensor part 200 and to the (e.g., entire) metal conductive part A. The eddy current reduction pattern part 300 may be formed in consideration of thermal conductivity for cooling, the location of the semiconductor chip 110, and the more area of the eddy current reduction pattern part 300 is secured, the more the generation of eddy currents may be reduced.

Meanwhile, the sensor part 200 may be electrically connected to the outside through a signal pin 400.

The signal pin 400 is electrically connected to the sensor part 200, and the voltage generated in the sensor part 200 may be applied to the signal pin 400.

At this time, the signal pin 400 is provided for electrical connection between components and may be made of a material such as a conductive metal. The signal pin 400 may be implemented in various ways other than the above example, and may be included in the signal pin of the present disclosure as long as an electrical connection between the inside and outside of the power module may be performed, regardless of material, shape and/or name=.

The signal pin 400 may be connected to an external control board, and the control board may obtain the current inside the power module by means of the voltage of the sensor part 200 received through the signal pin 400.

The sensor part 200 and the signal pin 400 may be connected in various ways.

As an example, in the metal conductive part A of the substrate 100, the segment S where the sensor part 200 is provided and the segment S for connection of the signal pin 400 are divided by the eddy current reduction pattern part 300, and the sensor part 200 may be electrically connected to the segment S to which the signal pin 400 is connected.

As such, the metal conductive part A of the substrate 100 is divided into the plurality of segments S by the eddy current reduction pattern part 300, and may be configured such that the segment S where the sensor part 200 is provided and the segment S to which the signal pin 400 is connected are electrically connected.

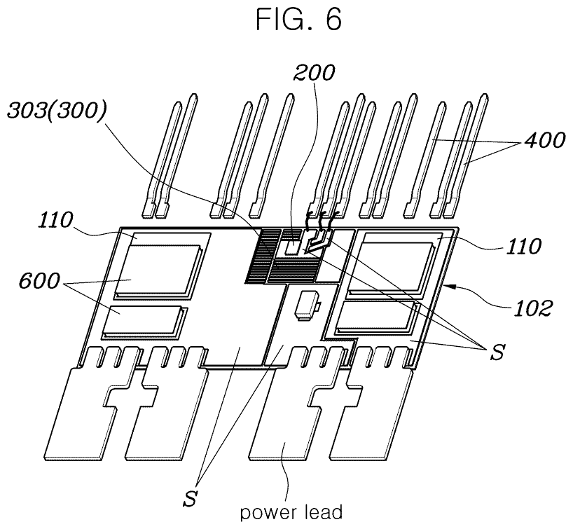

Referring to FIG. 6, as the segment S to which the signal pin 400 is connected is electrically connected to the outside, and the segment S where the sensor part 200 is provided is electrically connected to the segment S to which the signal pin 400 is connected, the electrical connection structure of the sensor part 200 may be configured.

Due to this, the signal pin 400 may receive the voltage generated in the sensor part 200 through individual segments S and transmit the received voltage back to the outside.

The sensor part 200, the signal pin 400, and the individual segments S may be electrically connected through a wire bonding connection, and an electrical connection structure may be configured through bonding.

As another example, the sensor part 200 may be electrically connected to the signal pin 400 through at least one of a wire bonding connection or bonding to the signal pin 400.

Referring to FIG. 1, the sensor part 200 may be connected to the signal pin 400 through wire bonding. The sensor part 200 may be electrically connected through bonding with the signal pin 400, and the method for connecting the sensor part 200 and the signal pin 400 may be applied in a mixed manner.

Various connection methods other than the above-described examples may be applied as the electrical connection method for the sensor part 200 and the signal pin 400.

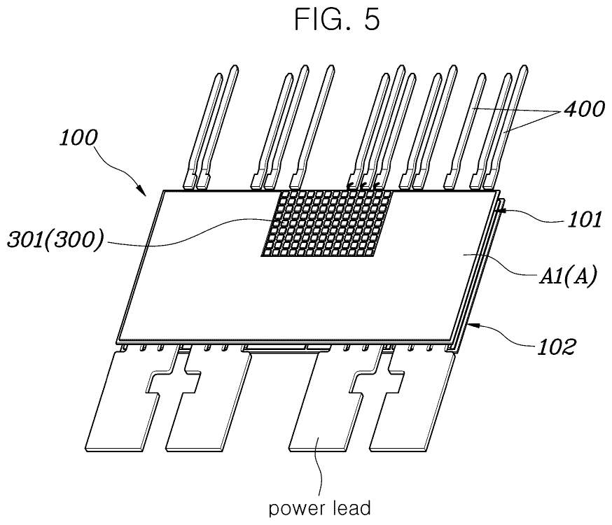

Meanwhile, as shown in FIG. 1, and FIGS. 5 to 10, the substrate 100 includes a first substrate 101 and a second substrate 102, and the sensor part 200 may be provided on either the first substrate 101 or the second substrate 102 and may sense the current flowing in the metal conductive part A of the opposing substrate 100.

The first substrate 101 and the second substrate 102 may be arranged to be spaced apart up and down. Expressions such as an up-and-down direction are intended to indicate relationships between each other for convenience of understanding and do not imply (e.g., absolute) directionality.

In this case, the first substrate 101 may include a first insulation part B1, and a first metal conductive part A1 and a second metal conductive part A2 respectively disposed on opposite sides of the first insulation part B1 centered on the first insulation part B1.

The second substrate 102 may include a second insulation part B2, and a third metal conductive part A3 and a fourth metal conductive part A4 respectively disposed on opposite sides of the second insulation part B2 centered on the second insulation part B2.

Accordingly, the second metal conductive part A2 of the first substrate 101 and the third metal conductive part A3 of the second substrate 102 are disposed to face each other. In the present disclosure, the semiconductor chip 110 is disposed on the second substrate 102, but the semiconductor chip 110 may be disposed on the first substrate 101. Additionally, the first substrate 101 and the second substrate 102 may be electrically connected through a spacer P.

The sensor part 200 may be provided on either the second metal conductive part A2 of the first substrate 101 or the third metal conductive part A3 of the second substrate 102. In the present disclosure, to facilitate understanding of the present disclosure, the sensor part 200 is provided in the third metal conductive part A3 of the second substrate 102, and a sensing object part for which the sensor part 200 senses the current flow may be a current path formed according to the shape of the eddy current reduction pattern part 300 in the second metal conductive part A2 of the first substrate 101.

In addition, the first metal conductive part A1 of the first substrate 101 and the fourth metal conductive part A4 of the second substrate 102 may serve to cool the power module by dissipating heat generated inside the power module to the outside through heat exchange with the outside.

Furthermore, in order to obtain more improved cooling efficiency, a cooling channel 500 through which a refrigerant flows may be connected to the outside of at least one of the first substrate 101 and the second substrate 102.

Meanwhile, each insulation part may be implemented, for example, with ceramic, and each metal conductive part A may be implemented with, for example, copper (Cu). In this case, the first substrate 101 and the second substrate 102 may be implemented using an active metal brazing (AMB) method or a direct bonded copper (DBC) method.

As a result, the sensor part 200 may be configured to sense current through the voltage generated according to the magnetic field caused by the current flowing through the first substrate 101 while being provided on the second substrate 102.

The sensor part 200 is composed of a Hall element, and the voltage generated by the Hall element may be referred to as Hall voltage.

The Hall voltage is produced in a direction perpendicular to both the magnetic field and the current flowing through the Hall element. In this case, the magnetic field may be viewed as being generated by the current flowing through the second metal conductive part A2 of the first substrate 101.

In this way, by providing the sensor part 200 inside the power module, current may be sensed without contacting an object to be sensed on the first substrate 101 using the above Hall effect.

In the first substrate 101 and the second substrate 102, the eddy current reduction pattern part 300 may be applied in various embodiments.

A first eddy current reduction pattern part 301 may be provided in the first metal conductive part A1 in a form that covers the sensor part 200 and the periphery of a portion matching the sensor part 200.

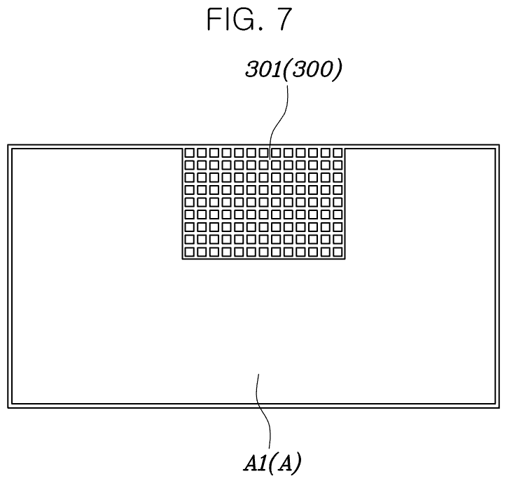

That is, as shown in FIG. 7, the first eddy current reduction pattern part 301 is provided in the first metal conductive part A1, which is the upper surface of the first substrate 101, and the first eddy current reduction pattern part 301 may be applied to cover the portion facing the sensor part 200 and the periphery thereof in a state in which the first substrate 101 and the second substrate 102 face each other.

The first eddy current reduction pattern part 301 may be applied in various ways, such as in the form of a grid or a form in which multiple straight lines are repeated, and in the area where the first eddy current reduction pattern part 301 is provided, the magnetic field caused by the current flow is suppressed to reduce eddy current.

The first eddy current reduction pattern part 301 may be formed over the (e.g., entire) area on the plane of the first metal conductive part A1, and the application range may be determined by considering cooling efficiency and/or eddy current reduction effect.

Meanwhile, the second metal conductive part A2 is divided into a plurality of segments S by a second eddy current reduction pattern part 302, and the sensor part 200 may be arranged to match a portion where the current path is formed among the segments S of the second metal conductive part A2.

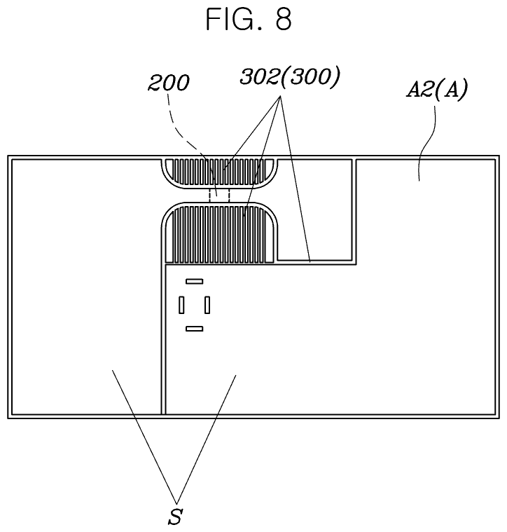

As shown in FIG. 8, the second eddy current reduction pattern part 302 may be provided on the second metal conductive part A2, which is the lower surface of the first substrate 101, and the second metal conductive part A2 is divided into the plurality of segments S by the second eddy current reduction pattern part 302. The shape of individual segment S of the second metal conductive part A2 may be determined depending on the current path of the first substrate 101 and the second substrate 102.

In this case, the sensor part 200 is arranged to match a portion where the current path is formed among the segments S of the second metal conductive part A2 on the second substrate 102, allowing the sensor part 200 to measure the current flowing through the first substrate 101.

In addition, the sensor part 200 may be arranged to match a portion with a smaller width or area among the segments S of the second metal conductive part A2. Referring to FIG. 8, the sensor part 200 is arranged to match a narrow portion among the segments S of the second metal conductive part A2, thereby minimizing the influence of the eddy current. This is because the eddy current is proportional to the flow of current flowing in the metal conductive part A and the frequency of current flow, and thus the wider the range of the metal conductive part A, the greater the influence of the eddy current on the sensor part 200.

The second eddy current reduction pattern part 302 may include a pattern shape in a (e.g. certain) range around the sensor part 200 in the segment S matching the sensor part 200. Accordingly, the second eddy current reduction pattern part 302 may be applied in various ways, such as in the form of a grid or a form in which multiple straight lines are repeated, in a (e.g., certain) range around the sensor part 200.

In addition, the second eddy current reduction pattern part 302 may be provided in the surrounding area of a portion matching the sensor part 200, excluding the current path so that the current path may be maintained in the second metal conductive part A2.

In this way, as the second eddy current reduction pattern part 302 is formed around the location matching the sensor part 200 in the second metal conductive part A2 of the second substrate 102, the magnetic field produced by the current flow is suppressed, thereby reducing eddy current.

Meanwhile, the third metal conductive part A3 may include a pattern shape in a (e.g., certain) range around the sensor part 200.

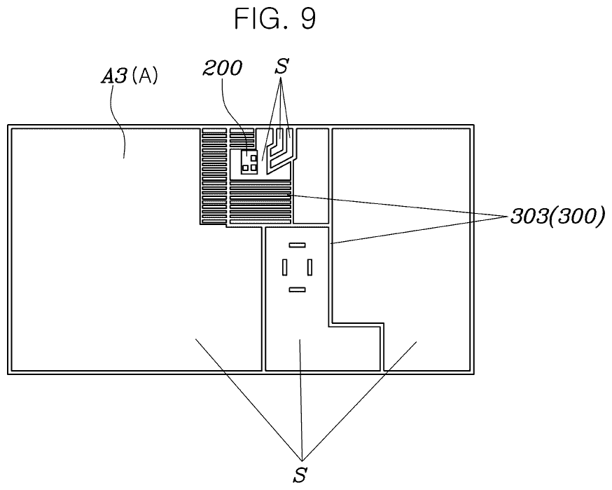

As shown in FIG. 9, a third eddy current reduction pattern part 303 may be provided on the third metal conductive part A3, which is the upper surface of the second substrate 102, and the third metal conductive part A3 is divided into the plurality of segments S by the third eddy current reduction pattern part 303. At this time, the shape of individual segment S of the third metal conductive part A3 may be determined depending on the current path of the first substrate 101 and the second substrate 102, and the sensor part 200 may be configured to be electrically separated from other segments S.

In addition, referring to FIG. 9, the third eddy current reduction pattern part 303 is applied to a (e.g., certain) range around the sensor part 200, and in the case of the segment S to which the signal pin 400 is connected, since the segment S is configured to be electrically separated from other segments S, an eddy current reduction effect may be achieved even if the pattern is not applied to the corresponding area.

The third eddy current reduction pattern part 303 may be applied in various ways, such as in the form of a grid or a form in which multiple straight lines are repeated, in a (e.g., certain) range around the sensor part 200, and the application range may be determined depending on the current path in each segment S and the thermal conductivity by means of the metal conductive part A.

Meanwhile, a fourth eddy current reduction pattern part 304 may be provided in the fourth metal conductive part A4 to cover the sensor part 200 and the periphery of a portion matching the sensor part 200.

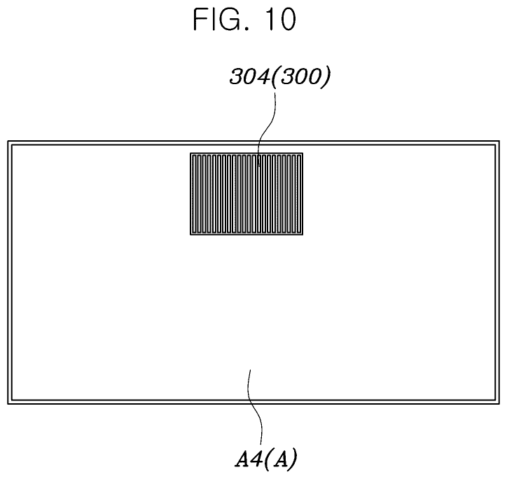

As shown in FIG. 10, the fourth eddy current reduction pattern part 304 is provided in the fourth metal conductive part A4, which is the lower surface of the second substrate 102, and the fourth eddy current reduction pattern part 304 may be applied to cover the portion of the second substrate 102 where the sensor part 200 is provided and the periphery thereof.

The fourth eddy current reduction pattern part 304 may be applied in various ways, such as in the form of a grid or a form in which multiple straight lines are repeated, and in the portion where the fourth eddy current reduction pattern part 304 is formed, the magnetic field produced by the current flow is suppressed to reduce eddy current.

The fourth eddy current reduction pattern part 304 may be formed over the (e.g., entire) area on the plane of the fourth metal conductive part A4, and the application range may be determined by considering cooling efficiency and/or eddy current reduction effect.

Meanwhile, the patterns of the above-described first, second, third, and fourth eddy current reduction pattern parts 301, 302, 303, and 304 may be applied differently.

As an embodiment of the present disclosure, as shown in FIGS. 7 and 10, in the first metal conductive part A1, the first eddy current reduction pattern part 301 in the form of a plurality of repeated grids is formed covering the sensor part 200 and the periphery of the portion matching the sensor part 200, whereas in the fourth metal conductive part A4, the fourth eddy current reduction pattern part 304 in the form of a plurality of repeated straight lines is formed covering the sensor part 200 and the periphery of the portion matching the sensor part 200.

That is, since on the first substrate 101, the sensor part 200 is not directly provided but an object for which the sensor part 200 measures current is provided, the first eddy current reduction pattern part 301 may have a grid shape that can facilitate the (e.g., greatest) eddy current reduction effect.

The sensor part 200 is provided on the second substrate 102 and measures the current flowing in the current path of the first substrate 101 on the opposite side, and the fourth eddy current reduction pattern part 304 in the fourth metal conductive part A4 may be applied in the form of repeated straight lines within the range of ensuring thermal conductivity performance and manufacturing convenience.

Meanwhile, in the second metal conductive part A2, the second eddy current reduction pattern part 302 is provided around the sensor part 200, and the second eddy current reduction pattern part 302 may be formed in the form of repeated straight lines, whereas in the third metal conductive part A3, the third eddy current reduction pattern part 303 is provided around the sensor part 200, and the third eddy current reduction pattern part 303 may be formed in the form of repeated straight lines but the extension direction of the straight lines may face a different direction from that of the second eddy current reduction pattern part 302.

As shown in FIGS. 8 and 9, the second eddy current reduction pattern part 302 and the third eddy current reduction pattern part 303 are formed to have opposite pattern shapes, so that the resistance generated around the sensor part 200 may be increased to reduce the occurrence of eddy currents, and eddy current loss may also be reduced.

Each embodiment of the above-described first, second, third, and fourth eddy current reduction pattern parts 301, 302, 303, and 304 is not limited to the above example, and each eddy current reduction pattern part may be implemented in various forms.

The power module with the structure described above may sense current through the Hall element provided therein, thereby reducing the volume and cost for current sensing. Furthermore, by reducing the influence of eddy currents on the Hall element, the sensing accuracy of the Hall element may be improved.

Although the present disclosure was provided above in relation to specific embodiments shown in the drawings, it is apparent to those skilled in the art that the present disclosure may be changed and modified in various ways without departing from the scope of the present disclosure, which is provided in the following claims.

What is claimed is:

1. A power module comprising:
a substrate provided with a semiconductor chip and a plurality of metal parts;
a sensor part disposed on a first side of the substrate where the semiconductor chip is located and configured to sense current flowing in the semiconductor chip or the metal part of the first side; and
an eddy current reduction pattern part including a plurality of segments in which at least one of the plurality of metal parts is divided to reduce an eddy current around the sensor part.

2. The power module of claim 1, further including:
an insulation part disposed between the plurality of metal parts, and
wherein the sensor part is disposed on a metal part of the plurality of metal parts located on the first side in a direction toward the semiconductor chip with respect to the insulation part.

3. The power module of claim 2, wherein the eddy current reduction pattern part is formed on the metal part of the first side.

4. The power module of claim 3, wherein the eddy current reduction pattern part is configured such that a segment where the sensor part is disposed is electrically separated from another segment of the plurality of segments.

5. The power module of claim 3, wherein the eddy current reduction pattern part is configured such that segments, other than a segment where the sensor part is disposed, of the plurality of segments are divided into multiple segments.

6. The power module of claim 3, wherein the eddy current reduction pattern part includes a range of pattern shapes around a segment of the plurality of segments where the sensor part is disposed.

7. The power module of claim 2, wherein the eddy current reduction pattern part is formed on the metal part of a second side of the substrate opposite to the first side.

8. The power module of claim 7, wherein the eddy current reduction pattern part is configured to cover the sensor part and a periphery of a portion matching the sensor part.

9. The power module of claim 8, wherein the eddy current reduction pattern part includes a repeated pattern shape.

10. The power module of claim 2, wherein the eddy current reduction pattern part is formed on each metal part of the plurality of metal parts.

11. The power module of claim 10, wherein the eddy current reduction pattern part is configured such that a segment, where the sensor part is disposed, is electrically separated from another segment of the plurality of segments.

12. The power module of claim 10, wherein the eddy current reduction pattern part is configured such that segments, other than a segment where the sensor part is disposed, of the plurality of segments are divided into multiple segments.

13. The power module of claim 10, wherein the eddy current reduction pattern part includes a range of pattern shapes around a segment of the plurality of segments where the sensor part is installed.

14. The power module of claim 10, wherein the eddy current reduction pattern part is configured to cover the sensor part and a periphery of a portion matching the sensor part.

15. The power module of claim 14, wherein the eddy current reduction pattern part includes a repeated pattern shape.

16. The power module of claim 1, wherein the substrate includes a first substrate and a second substrate, and the sensor part is provided on the first substrate or the second substrate and the sensor part is configured to sense current of the substrate opposing each other.

17. The power module of claim 16, wherein
the first substrate includes
a first insulation part, and
a first metal part and a second metal part respectively disposed on opposite sides of the first insulation part centered on the first insulation part, and the second substrate includes
a second insulation part, and
a third metal part and a fourth metal part respectively disposed on opposite sides of the second insulation part centered on the second insulation part, and
the sensor part is provided in the second metal part or the third metal part located on an inner side where the first substrate and the second substrate face each other.

18. The power module of claim 17, wherein the eddy current reduction pattern part is formed on at least one of the first metal part, the second metal part, the third metal part, or the fourth metal part.

19. The power module of claim 1, wherein the sensor part is electrically connected to an outside through a signal pin.

20. The power module of claim 1, wherein the sensor part is a Hall element that generates a voltage by using a magnetic field produced by current flowing in a metal part of the plurality of metal parts of the substrate.
